(19) United States
(12) Patent Application Publication
(10) Pub. No.: US 2024/0363445 A1
(43) Pub. Date: Oct. 31, 2024

(54) DUMMY DIE MATERIAL SELECTION AND POSITIONING FOR BONDING PROCESSES

(71) Applicant: Applied Materials, Inc., Santa Clara, CA (US)

(72) Inventor: Vincent Luc Paul RIPOCHE, Strasbourg (FR)

(21) Appl. No.: 18/140,900

(22) Filed: Apr. 28, 2023

(51) Int. Cl. H01L 21/66; G06N 20/00; H01L 23/00

(52) U.S. Cl. CPC H01L 22/12; G06N 20/00; H01L 24/80; H01L 2224/80895; H01L 2224/80896

(57) ABSTRACT

In some embodiments, a method is provided that selects the thermal-mechanical three-dimensional properties of a dummy die for a bonding wafer based on obtaining a more homogeneous coefficient of thermal expansion or thermal conductivity control to alter heat extraction. In some embodiments, a method is provided that also selects properties and positioning of a dummy die based on subsequent processes that occur after bonding of dies to a bonding wafer. Placement of the dummy dies allows edge management control for chemical-mechanical polishing. In some embodiments, metrology feedback may be used to allow dummy die positioning based on non-functional dies bonded to a bonding wafer.

### FIELD

Embodiments of the present principles generally relate to semiconductor processing of semiconductor substrates.

### BACKGROUND

In order to form processing circuits or logic circuits and similar integrated chip structures, individual dies are singulated and bonded to bonding wafers. The bonding wafers may then undergo further processing such as gapfill processes which require subsequent planarization and the like. The inventor has observed that the subsequent processes are often substantially impacted by the die height, die placement, and die density on the bonding wafer, both at wafer center and wafer edge.

Accordingly, the inventor has provided methods for improving bonding wafer performance in post-bonding processes.

### SUMMARY

Methods for improving bonding wafer performance in post-bonding processes by utilizing dummy dies during hybrid bonding processes are provided herein.

In some embodiments, a method for dummy die placement on a bonding wafer may comprise receiving bonding wafer parameters for the bonding wafer, receiving component die size parameters for at least one component die and component die positioning parameters of the at least one component die for the bonding wafer, receiving bonding wafer processing information for at least one subsequent post-bonding process for the bonding wafer, determining dummy die size parameters, dummy die material composition, or dummy die positioning parameters on the bonding wafer based on the at least one subsequent post-bonding process or thermal behavior of a dummy die material or a wafer material of the bonding wafer, selecting at least one dummy die according to the dummy die size parameters, dummy die material composition, or dummy die positioning parameters, and bonding the at least one dummy die on the bonding wafer according to the dummy die positioning parameters.

In some embodiments, the method may further include bonding wafer parameters that include a size of the bonding wafer or a material composition of the bonding wafer, component die size parameters that include a width, a length, and a height of a component die, dummy die size parameters that include a width, a length, and a height for a dummy die, dummy die material composition that includes dielectric material and metallic material, using a machine learning model that receives the bonding wafer parameters, the component die size parameters, the component die positioning parameters, and the bonding wafer processing information and infers the dummy die size parameters, the dummy die material composition, or the dummy die positioning parameters for the bonding wafer, using the machine learning model to infer dummy die size parameters and dummy die positioning parameters that maintain edge uniformity of the bonding wafer during the at least one subsequent post-bonding process, using the machine learning model to infer dummy die size parameters and dummy die positioning parameters that reduce step height differences between the at least one component die bonded on the bonding wafer and a surrounding area of the at least one component die bonded on the bonding wafer, determining the dummy die material composition based on thermal expansion or conduction properties of the at least one component die, at least one subsequent post-bonding process that includes an, annealing process, a chemical mechanical planarization (CMP) process, a chemical vapor deposition (CVD) gapfill process, or a plating gapfill process, and/or performing the method integrated into an integrated hybrid bonding tool or performing the method external to the integrated hybrid bonding tool.

In some embodiments, a method for dummy die placement on a bonding wafer may comprise receiving bonding wafer parameters for the bonding wafer, wherein the bonding wafer parameters include a size of the bonding wafer or a material composition of the bonding wafer, receiving component die size parameters for at least one component die and component die positioning parameters of the at least one component die for the bonding wafer, wherein the component die size parameters include a width, a length, and a height of the component die, receiving bonding wafer processing information for at least one subsequent post-bonding process for the bonding wafer, inferring dummy die size parameters, dummy die material composition, or dummy die positioning parameters on the bonding wafer using a machine learning model that incorporates the bonding wafer parameters, the component die size parameters, the component die positioning parameters, and the bonding wafer processing information to select at least one dummy die, and bonding the at least one dummy die on the bonding wafer according to the dummy die positioning parameters.

In some embodiments, the method may further include dummy die size parameters that include a width, a length, and a height for a dummy die, dummy die material composition that includes dielectric material and metallic material, using the machine learning model to infer dummy die size parameters and dummy die positioning parameters that maintain edge uniformity of the bonding wafer during the at least one subsequent post-bonding process, using the machine learning model to infer dummy die size parameters and dummy die positioning parameters that reduce step height differences between the at least one component die bonded on the bonding wafer and a surrounding area of the at least one component die bonded on the bonding wafer, and/or determining the dummy die material composition based on thermal expansion or conduction properties of the at least one component die.

In some embodiments, a non-transitory, computer readable medium having instructions stored thereon that, when executed, cause a method for dummy die placement on a bonding wafer to be performed, the method may comprise receiving bonding wafer parameters for the bonding wafer, receiving component die size parameters for at least one component die and component die positioning parameters of the at least one component die for the bonding wafer, receiving bonding wafer processing information for at least one subsequent post-bonding process for the bonding wafer, determining dummy die size parameters, dummy die material composition, or dummy die positioning parameters on the bonding wafer based on the at least one subsequent post-bonding process or thermal behavior of a dummy die material or a wafer material of the bonding wafer, selecting at least one dummy die according to the dummy die size parameters, dummy die material composition, or dummy die positioning parameters, and bonding the at least one dummy die on the bonding wafer according to the dummy die positioning parameters.

In some embodiments, the method may further include using a machine learning model that receives the bonding wafer parameters, the component die size parameters, the component die positioning parameters, and the bonding wafer processing information and infers the dummy die size parameters, the dummy die material composition, or the dummy die positioning parameters for the bonding wafer, and/or determining dummy die size parameters, dummy die material composition, or dummy die positioning parameters on the bonding wafer based on metrology information of the bonding wafer.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a process flow for hybrid bonding in accordance with some embodiments of the present principles.

FIG. 2 depicts a process flow for post-bonding processes in accordance with some embodiments of the present principles.

FIG. 3 depicts top-down and cross-sectional views of a bonding wafer with component dies in accordance with some embodiments of the present principles.

FIG. 4 depicts a cross-sectional view of a bonding wafer with component dies after a gapfill process in accordance with some embodiments of the present principles.

FIG. 5 depicts a top-down view and a cross-sectional view of a bonding wafer with component dies and dummy dies in accordance with some embodiments of the present principles.

FIG. 6 depicts a cross-sectional view of a bonding wafer with component dies and dummy dies after a gapfill process in accordance with some embodiments of the present principles.

FIG. 7 depicts a cross-sectional view of thermal expansion of a component die and a dummy die in accordance with some embodiments of the present principles.

FIG. 8 depicts a cross-sectional view of a dummy die used in place of a component die for a nonfunctional bottom component die in accordance with some embodiments of the present principles.

FIG. 9 is a method of selecting and positioning dummy dies in accordance with some embodiments of the present principles.

FIG. 10 depicts a cross-sectional view of an automatic dummy die placement system in communication with a hybrid bonder and post-bonding processes to enable process feedback in accordance with some embodiments of the present principles.

FIG. 11 is a top-down view of a hybrid bonding tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide improved bonding wafer performance to allow enhanced subsequent processing procedures by leveraging dummy die usage during die-to-wafer hybrid bonding processes. The methods allow for homogeneous surroundings for bonded dies through the use of same height dummy dies versus large die surroundings with 15 to 150 microns step height, making for much easier post-bond integration. Homogenous surroundings for a die also allow for cheaper gapfill processing due to less overburden. The present techniques also advantageously provide an edge management solution for subsequent substrate polishing processes, such as chemical mechanical polishing (CMP), by positioning dummy dies for optimal edge control. The methods can also be incorporated into complex die-to-wafer integration processes in integrated hybrid bonding platforms. Such an automatic feature provided by the present methods can be a key differentiator, providing lower integration costs and higher yields. The methods can be further enhanced using integration software, dummy die reservoirs or feeds, and a multiple size hybrid bonding machine.

In traditional die-to-wafer bonding, the bonding wafer will have dies of largely varying die heights (e.g., 15 to 150 microns, etc.) that are bonded to the bonding wafer. During subsequent processing, the huge step height (difference in die heights to surrounding unpopulated areas) needs to be filled/planarized in a way that allows stacking and backside processes. Any large gaps between dies and especially at the bonding wafer edge are very challenging. Chip packaging manufacturers will not lower die yield by sacrificing known-good-dies to populate the edges (i.e., area from about 2 mm to about 10 mm from the wafer's edge), and no die can extend beyond wafer edge. The subsequent processes after bonding will have difficulty handling the gaps and exposed corners (e.g., subsequent processes such as, but not limited to, gapfill, chemical mechanical polishing, plating, through silicon via (TSV) openings, etc.), increasing yield risks and costs.

As used herein, a component die is a die that forms part of a semiconductor device, active or passive, and may include processors, logic, memory, interposers, and the like. The methods of the present principles provide the ability to automatically position dummy dies (for example, silicon-based dummy dies, etc.) to homogenize the surroundings of each component die. The methods can be incorporated directly into manufacturing integration costs. The methods can calculate dummy needs and placements and balances integrated hybrid bonding tool output. The methods can also incorporate feedback and feedforward capabilities from other semiconductor processing tools to incorporate subsequent processes into the dummy die process model such as CMP edge management, chemical vapor deposition (CVD) performance, and the like to optimize dummy die utilization and placement. By leveraging subsequent processing requirement knowledge, the dummy die process can be minimized to a one or more optimized die sizes which minimizes the impact on hardware such as in a die-to-wafer hybrid bonding integrated tool (e.g., possibly requiring only one additional die bonder for the dummy dies in the integrated tool, etc.).

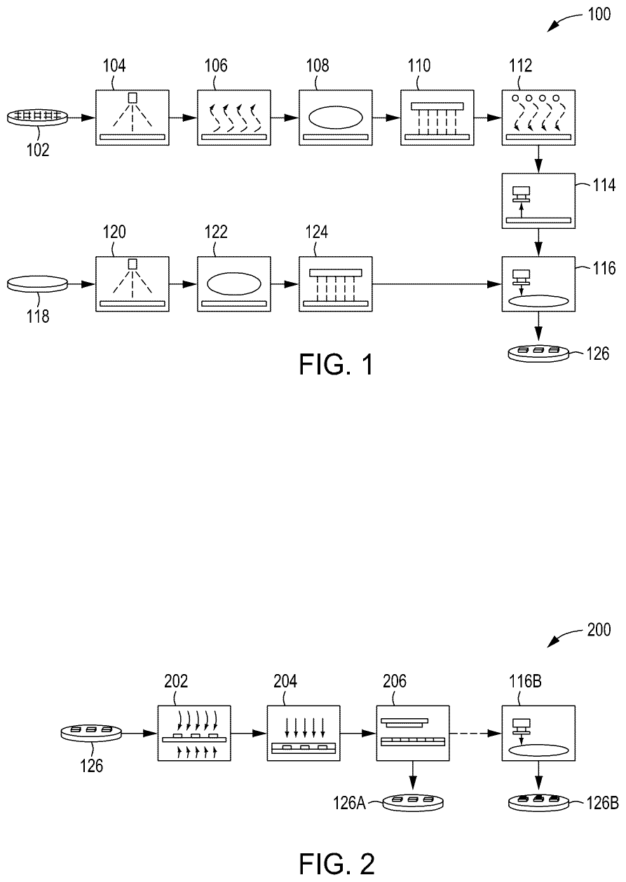

FIG. 1 depicts an example of a hybrid bonding process 100 for a target 118 that is a bonding wafer that component dies will be bonded to and a source 102 that is a wafer with component dies that are removed from the source 102 for bonding to the target 118. The hybrid bonding process 100 is an example bonding process and other such processes can be performed with fewer or more processes. As such, the hybrid bonding process 100 is not meant to be limiting. In a bonding process, both component dies (source) and targets (bonding wafer) on which the component dies are to be bonded are prepared prior to bonding to enhance the bonding performance. In some cases, the source 102 can be processed in parallel, prior to, or after a target 118 on which a component die from the source 102 is to be bonded. As used herein, a source may be a wafer or substrate that provides a film frame, a chiplet, a top die, or a component die for bonding to a target such as a substrate, base wafer, base die, or unit, respectively. For the sake of brevity, and not meant to be limiting, the term ‘component die’ will be used herein to refer to a film frame, a chiplet, a top die, or a component supplied by a source which is to be bonded to a target.

The source 102 may undergo other processes prior to the hybrid bonding processes. The other processes may include upstream processing such as patterning, CMP, back grinding, dicing, and the like. In some embodiments, for example, component dies may be separated (singulated) and held together on the back side by dicing tape to create the source 102. In some embodiments, component dies may be reconstituted (molded) on a carrier wafer to form the source 102 from which component dies are selected for bonding. In the hybrid bonding process 100, in some embodiments, the source 102 typically undergoes a first wet clean process 104 and then a degassing process 106 to aid in removing moisture from the source 102. The source 102 is then subjected to a first plasma activation process 108 to increase bonding attraction and then subjected to a first hydration process 110. The source 102 is then subjected to a radiation process 112 (e.g., UV radiation, etc.) to loosen an adhesive bond holding the component dies to the source 102 prior to bonding. In some embodiments, the target 118 may undergo other processes prior to the hybrid bonding process 100. The target 118 is processed prior to, in conjunction with, or after the processing of the source 102. In some embodiments, the target 118 first undergoes a second wet cleaning process 120 and is then subjected to a second plasma activation process 122. The target 118 then undergoes a second hydration process 124 in preparation for bonding.

Bonding is then accomplished by subjecting the source 102 to an ejection and picking process 114 that allows a component die to be selected and flipped in preparation for bonding. In a bonding process 116, the die is placed on the target 118 and the component die bonds to the target 118 yielding a die-to-target bonded target or bonding wafer 126. The bonding wafer 126 may have a plurality of component dies bonded to the surface during one or more bonding sessions. FIG. 2 is an example of a post-bonding process flow 200. In some embodiments, a low temperature annealing process 202 is performed on the bonding wafer 126 to reflow connections of the component die and bonding wafer 126 to further bond the connections. The bonding wafer 126 may then undergo a gapfill process 204. The gapfill process 204 may use a CVD deposition process or a plating process and the like to deposit gapfill material on the bonding wafer 126. The gapfill material fills the gaps between the component dies bonded to the bonding wafer 126. Overburden, or excess gapfill material, is then removed through CMP planarization processes 206 to form a completed bonding wafer 126A. In some embodiments, after planarization, the bonding wafer 126 is sent back to the bonder where additional component dies are then bonded on the previously bonded component dies in a second bonding process 116B to form a multiple component die stack bonding wafer 126B. The above post-bonding process flow is exemplary and not meant to be limiting. Other processes, such as metrology processes and the like may also be performed prior to or after bonding.

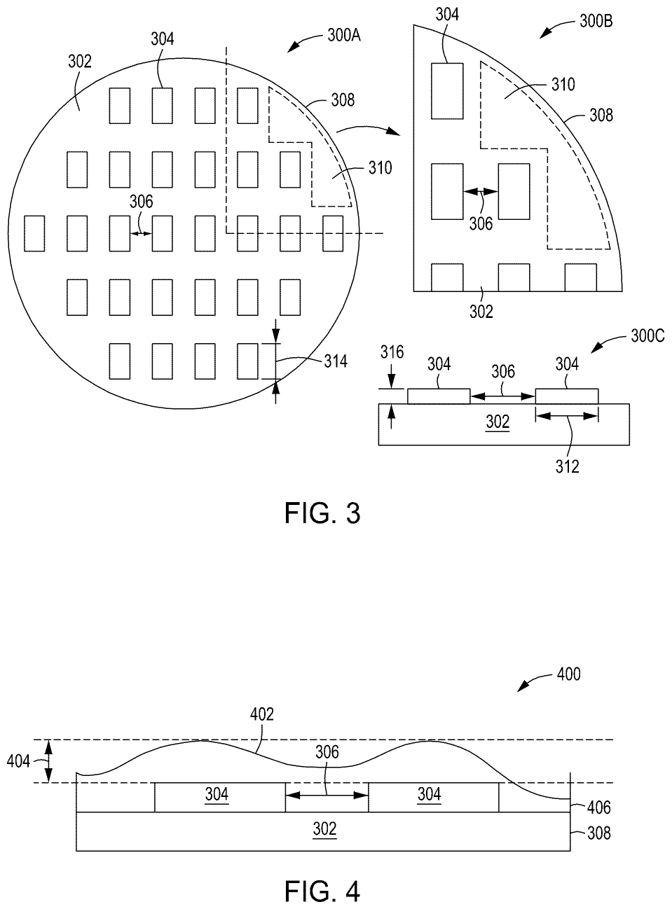

A view 300A of FIG. 3 depicts a bonding wafer 302 that has multiple component dies 304 bonded to the bonding wafer 302 after a hybrid bonding process such as the example process discussed above. The component dies 304 are typically arranged in an orderly fashion with a gap 306 between the component dies 304. The circular shape of the bonding wafer 302 combined with a typical rectangular shape of the component dies 304 precludes complete use of the surface of the bonding wafer 302, leaving large areas 310 without component dies, especially near the edge 308 of the bonding wafer 302. A view 300B depicts an enlarged portion of the bonding wafer 302 that better illustrates the gap 306 between component dies and the large areas 310 without component dies 304. A view 3000 of FIG. 3 depicts a cross-section of the bonding wafer 302 that shows the gap 306 between component dies 304 and a height 316 of the component dies 340. In some instances, the gap 306 may be from approximately 10 microns to approximately 50 millimeters. In some instances, the height 316 of the component dies may range from approximately 15 microns to approximately 150 microns. The component dies 304 will also have a length 314 and a width 312.

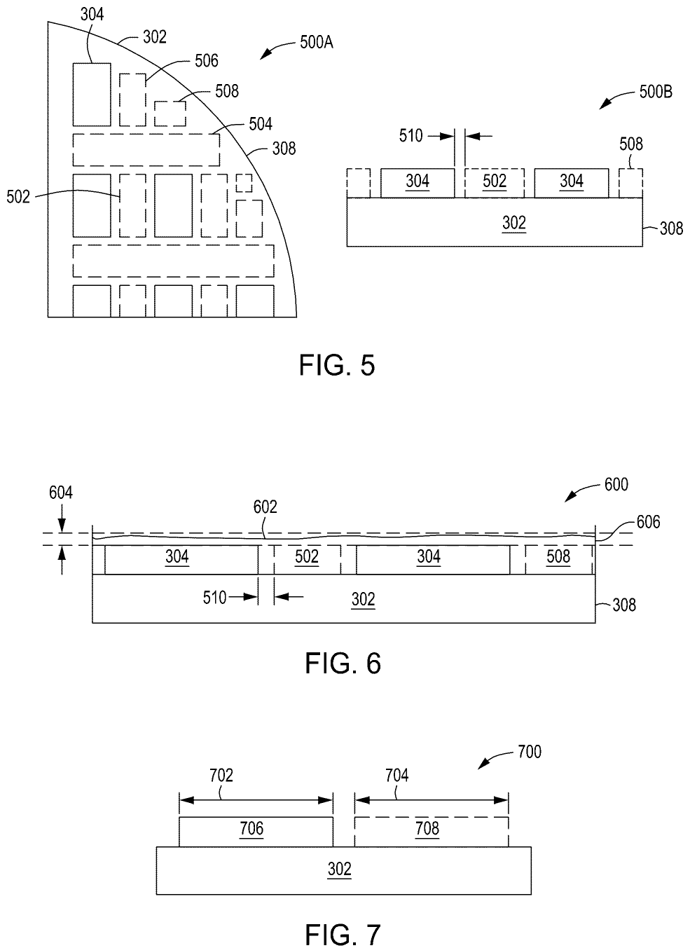

The inventor observed that during post-bonding processing the gap 306 and height 316 of the component dies 304 had negative impacts on the post-bonding processes as depicted in a view 400 of FIG. 4. During a gapfill process, such as with plating or CVD deposition, a heavy deposition (thickness) of gapfill material 402 is required to fill the gap 306. The heavy deposition causes a large amount of overburden 404 that must be removed during a subsequent planarization (CMP) process, causing reduced throughput (more time to planarize) and increased costs. The inventor also observed that the large areas 310 near the edge 308 caused a thinning 406 of the gapfill material near the edge 308, forming a nonuniformity of the bonding wafer 302 even after planarizing. The inventor discovered that if dummy dies 502-508 are positioned in the gaps and/or empty areas near the edges of the bonding wafer as depicted in a view 500A of FIG. 5, the impact of the above issues can be significantly reduced. As used herein, a dummy die has a composition of one or more materials with a similar height as component dies bonded to a bonding wafer. The dummy die may have different length and width dimensions than the component dies such that the dummy dies can be placed in gaps between component dies and/or along edges of the bonding wafer. In the example of view 500A, four different sizes (widths by lengths) of dummy dies 502-508 are shown but are not meant to be limiting in size or in number of available dummy die sizes. In a view 500B of FIG. 5, a cross-sectional view of the bonding wafer 302 is illustrated with a first size dummy die 502 positioned between component dies 304 and a second size dummy die 508 positioned near the edge 308 of the bonding wafer 302. The dummy dies effectively reduce the gap 306 to a smaller gap 510 and also reduce the component die step height difference between surrounding areas of the component die.

During subsequent gapfilling processes of gapfill material 602 as depicted in a view 600 of FIG. 6, the amount of overburden 604 was substantially reduced by using the dummy dies to reduce the gap 306 between component dies 304 to the smaller gap 510. The reduced overburden increased the yield (less time spent planarizing) and the decreased the costs. In addition, use of the second size dummy die 508 near the edge 308 of the bonding wafer 302 allowed a much higher uniformity 606 of the deposited gapfill material 602 near the edge 308, maintaining the integrity (sufficient gapfill material) of the component dies near the edge 308 of the bonding wafer 302. The inventor also found that if the thermal expansion coefficient (CTE or coefficient of thermal expansion) of the component dies and the dummy dies is substantially different, the quality of the subsequent processing of the bonding wafer 302 may be affected. In a view 700 of FIG. 7, a dummy die 708 with a first thermal expansion coefficient is positioned next to a component die 706 with a second thermal expansion coefficient. During subsequent post-bonding processes such as annealing, gapfilling, and/or planarizing, the bonding wafer 302 undergoes increases in temperature which causes the dummy die 708 to expand to a first expansion width 704 and the component die 706 to expand to a second expansion width 702.

CTE is not the only thermal issue related to temperature. Heat confinement, such as heat within an underlying die and the like, may be caused by poor thermal extraction conditions. In some embodiments, the dummy die material selection can be used to tune the dummy die to provide a better thermal conductance than dielectric materials. The tuning can greatly enhance heat transfer, homogenization, and, therefore, heat extraction. For example, a silicon dummy die could be used for thermal control rather than a dielectric dummy die as silicon has better heat spreading characteristics. Although silicon is used as an example, the use of silicon materials for the dummy die is not meant to be limiting as to materials that provide enhanced thermal properties for heat extraction and the like. Thus, in some embodiments, when determining dummy die size parameters, dummy die material composition, or dummy die positioning parameters on a bonding wafer, the selection of materials may be based on thermal behavior of the dummy die material (e.g., enhance thermal extraction or match CTE, etc.)

If the first thermal expansion coefficient of the dummy die is greater than the second thermal expansion coefficient of the component die, the first expansion width 704 of the dummy die 708 may be greater than the gap width between the dummy die 708 and the component die 706 creating compression/tensile forces and possibly cracking or chipping between component dies or between the dummy die 708 and the bonding wafer 302. The inventor found that the thermal expansion issues can be mitigated by forming a dummy die 708 with a substantially similar thermal coefficient as the component die 706. The dummy die's thermal expansion coefficient may be selected based upon use of a single material such as a dielectric for the dummy die or by using a composition of materials for the dummy die. In some instances, the dummy die may also include metallic content such as, but not limited to, similar metallic content by weight or composition as found in a component die or simulated redistribution layers and the like to ensure metallic distribution throughout the dummy die similar to the component die.

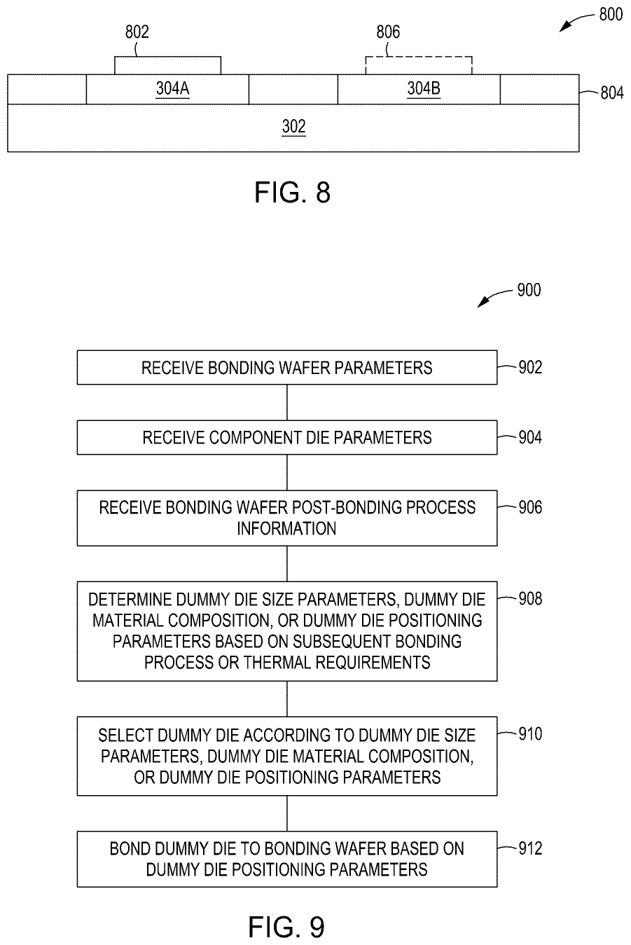

As noted above, the bonding wafer 302 may undergo more than one bonding process to create multiple die stacks on the bonding wafer 302 as depicted in a view 800 of FIG. 8. In the view 800, a first layer 804 of component dies and gapfill has been completed. However, for example, during subsequent metrology testing, a first component die 304A has been found to meet performance criteria, but a second component die 304B has been found to be nonfunctional. Because the bonding wafer 302 is to undergo more bonding layers to create the multiple component die stacks, placing a functional component die 802 on top of the second component die 304B that is nonfunctional would effectively increase production costs and reduce yields because the second layer component die would be wasted. As an alternative to wasting a functional component die 802, the metrology data can be fed back into a dummy die process such that a dummy die 806 can be placed on the nonfunctional die (second component die 304B) to avoid the use of and loss of a functioning die in a second layer.

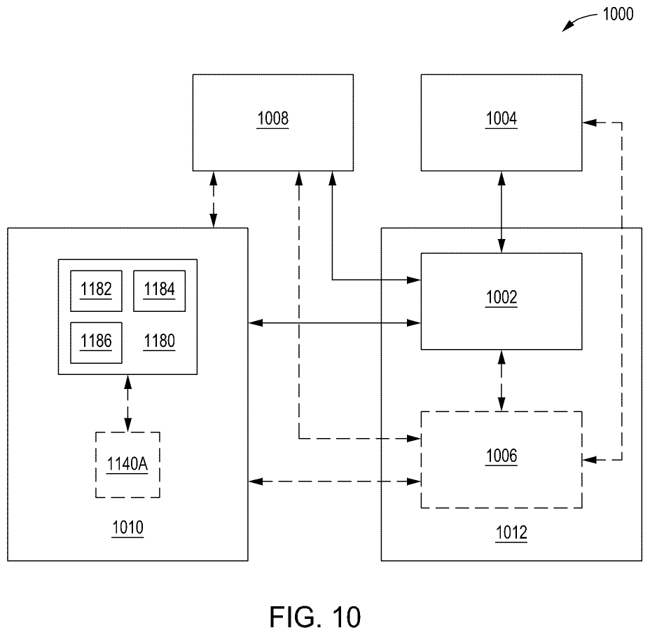

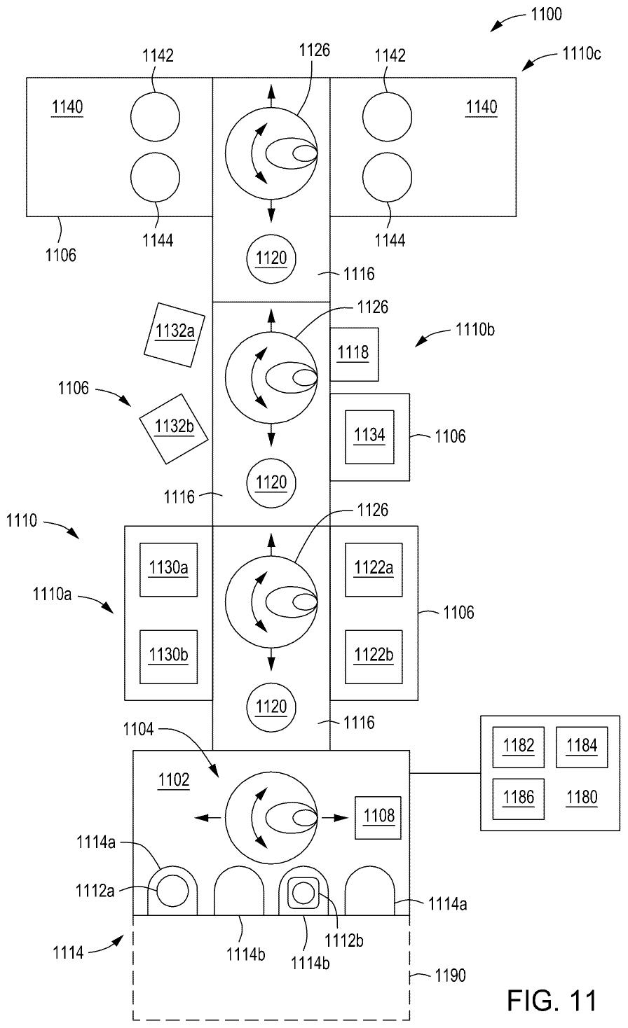

In block 902 of a method 900 of FIG. 9, bonding wafer parameters are received by, for example, a dummy die processor, such as the dummy die processor 1002 of FIG. 10. The dummy die processor 1002 may be external to or part of a hybrid bonding tool such as the tool described further below in FIG. 11. In some embodiments, the bonding wafer parameters may include, but are not limited to, size (e.g., diameter such as 200 mm, 300 mm, 450 mm, etc.), thickness, and/or material composition and the like. For example, the material composition of the wafer may influence the material composition selection for the dummy die. Similarly, the size of the bonding wafer may influence the size and placement of the dummy die. In block 904, component die parameters are received by, for example, the dummy die processor 1002. In some embodiments, the component die parameters may include, but not limited to, size parameters (width, length, and height), positioning/layout parameters for the bonding wafer, and/or material composition of the component die. In some embodiments, as discussed above, the height of the component die has a direct influence on the selection of the dummy die as to selecting a dummy die with a substantially similar height as the component die. The positioning/layout parameters (gaps between component dies and/or distances between component dies and bonding wafer edges, etc.) of the component die on the bonding wafer also directly impact the width and length selection possibilities of the dummy dies.

In block 906, bonding wafer post-bond process information is received, for example, by the dummy die processor 1002. In some embodiments, the bonding wafer post-bond process information may include, but not limited to, metrology processes, annealing processes, gapfilling processes, planarization processes, and the like that are performed after dies are bonded. The dummy die processor 1002 may receive knowledge of which processes are to be performed and/or actual feedback from the post-bonding processes 1004 from prior post-bonding processing. In block 908, dummy die size parameters, dummy die material composition, and/or dummy die positioning parameters are determined based on at least one subsequent post-bonding process or thermal behavior of a dummy die material or a wafer material of the bonding wafer. In some embodiments, dummy die size parameters may include, but are not limited to, a width, a length, and/or a height of a dummy die. In some embodiments, the dummy die material composition may include dielectric materials or dielectric and metallic materials, and the like. In some embodiments, the dummy die material composition is based upon the thermal expansion and/or thermal conductivity properties of a component die.

The dummy die processor 1002, given the layout position and size of the component dies, can determine areas of which dummy dies can be positioned and also sizes of dummy dies that will fit within the areas. For a given, post-bonding process such as planarization, the dummy die processor 1002 can determine that dummy dies should be positioned within 2 or 3 mm of the bonding wafer edge to ensure planarization uniformity and the like. Similarly, with knowledge of the component die parameters such as thermal expansion coefficient, a dummy die with appropriate material composition can be selected. In some embodiments, the number of dummy die sizes and/or material compositions may be reduced such that throughput is not dramatically affected. The more sizes used, the more bonders required and the more storage of dummy die size/material sources. In block 910, a dummy die is automatically selected according to the dummy die size parameters (e.g., sizes that fit versus sizes that are available to be bonded, etc.), the dummy die material composition (e.g., desired thermal expansion coefficient, thermal conductivity, compatibility with substrate material, etc.), and/or the dummy die positioning parameters (e.g., smaller dummy dies for edge locations, etc.), and the like.

In some embodiments, the determination of dummy die parameters and selection of the dummy die may be inferred using machine learning based on a dummy die model 1006 (see FIG. 10). The dummy die model 1006 incorporates bonding wafer parameters for the bonding wafer, component die parameters, and/or subsequent post-bonding processes that the bonding wafer will undergo after bonding. In some embodiments, machine learning is used in conjunction with the dummy die model 1006 to infer dummy die size parameters and dummy die positioning parameters that maintain edge uniformity of the bonding wafer during at least one subsequent post-bonding process. In some embodiments, machine learning is used in conjunction with the dummy die model 1006 to infer dummy die size parameters and dummy die positioning parameters that reduce step height differences of component dies and surrounding areas of the component dies on the bonding wafer. The dummy die model 1006 may also incorporate ‘lessons learned’ from results of prior post-bonding processing and prior selections of dummy die sizes, materials, and/or positioning. Information can be fed back into the dummy die model 1006 in real-time as post-bonding processes are being performed or after the post-bonding processes have completed either via the dummy die processor 1002 and/or directly into the dummy die model. Inferences may also be made to minimize the number of dummy die sizes versus performance tradeoffs during the subsequent post-bonding processes.

In block 912, the selected dummy die or dies are bonded to the bonding wafer based on the dummy die positioning parameters that were determined and/or inferred as described above. In some embodiments, a hybrid bonding integrated tool may have two bonders. The first bonder may be used to bond the component dies to the bonding wafer. The second bonder may then be used to bond the dummy dies to the bonding wafer. In an alternate embodiment, the selection and bonding of the dummy die may be based upon metrology data from a metrology tool 1008 (see FIG. 10). If the metrology tool 1008 determines that a component die is nonfunctional, a dummy die may be selected to replace a stacked component die during subsequent post-bonding processes. The substitution of the dummy die in place of the stacked component die allows for the process to eliminate waste of good known component dies when a previously bonded component die has been determined to be nonfunctional, maintaining throughput and increasing yield through less waste of good known component dies.

An automatic dummy die placement system 1012 may be used in conjunction with a hybrid bonder 1010 (also see FIG. 11) to improve post-bonding processes to a bonding wafer as depicted in a view 1000 of FIG. 10. The hybrid bonder 1010 is typically controlled by a controller 1180 (for more detail, see FIG. 11 below). In some embodiments, the automatic dummy die placement system 1012 may reside partially or wholly within the controller 1180 of the hybrid bonder 1010. In some embodiments, the automatic dummy die placement system 1012 resides externally of the hybrid bonder 1010. The controller 1180 accepts input from the automatic dummy die placement system 1012 with regard to selection of dummy dies and positioning of dummy dies on a bonding wafer. In some embodiments, the automatic dummy die placement system 1012 may include a dummy die processor 1002 configured to perform the methods disclosed herein. The dummy die processor 1002 makes automatic selections and positioning of dummy dies for the hybrid bonder 1010 based on inputs for the bonding wafer, component die parameters, and/or dummy die type and/or size availability. Inputs may also be obtained from the metrology tool 1008 as to component die functionality status and the like. The dummy die processor 1002, as previously mentioned, also receives input data about and/or directly from post-bond processes and the like, in real-time or after process completion. In some embodiments, the automatic dummy die placement system 1012 may also include a dummy die model 1006 that allows for machine learning inferences with regard to dummy die selection and positioning on a bonding wafer. The dummy die model 1006 may receive input directly from the metrology tool 1008, the post-bonding processes 1004, and/or the hybrid bonder 1010. In some embodiments, one bonder chamber 1140 (see FIG. 11) of the hybrid bonder 1010 may be dedicated to bonding dummy dies (dummy die bonder 1140A) selected by the automatic dummy die placement system 1012. The dummy die bonder 1140A may be in communication directly with the dummy die placement system 1012 and/or indirectly via the controller 1180 of the hybrid bonder 1010.

Automatic dummy die selection and bonding processes can be incorporated independent of or within various hardware structures (dummy die processes are discussed above and further below). For example, in FIG. 11, a schematic top view of an integrated hybrid bonding tool 1100 for bonding dies to a target is depicted in accordance with at least some embodiments. The methods described above and further below may be performed with the integrated hybrid bonding tool 1100. The integrated hybrid bonding tool 1100 generally includes an equipment front end module (EFEM) 1102 and a plurality of automation modules 1110 that are serially coupled to the EFEM 1102. The plurality of automation modules 1110 are configured to shuttle one or more types of substrates 1112 from the EFEM 1102 through the integrated hybrid bonding tool 1100 and perform one or more processing steps to the one or more types of substrates 1112 (e.g., source with component dies, source with dummy dies, a target or bonding wafer to bond the dies to, etc.). Each of the plurality of automation modules 1110 generally include a transfer chamber 1116 and one or more process chambers 1106 coupled to the transfer chamber 1116 to perform the one or more processes. The plurality of automation modules 1110 are coupled to each other via their respective transfer chamber 1116 to provide modular expandability and customization of the integrated hybrid bonding tool 1100. As depicted in FIG. 11, the plurality of automation modules 1110 comprise three automation modules, where a first automation module 1110a is coupled to the EFEM 1102, a second automation module 1110b is coupled to the first automation module 1110a, and a third automation module 1110c is coupled to the second automation module 1110b.

The EFEM 1102 includes a plurality of load ports 1114 for receiving one or more types of substrates 1112. In some embodiments, the one or more types of substrates 1112 include 200 mm wafers, 300 mm wafers, 450 mm wafers, tape frame substrates, carrier substrates with or without reconstituted dies, silicon substrates, glass substrates, or the like. In some embodiments, the plurality of load ports 1114 include at least one of one or more first load ports 1114a for receiving a first type of substrate 1112a or one or more second load ports 1114b for receiving a second type of substrate 1112b. In some embodiments, the first type of substrates 1112a have a different size than the second type of substrates 1112b. In some embodiments, the second type of substrates 1112b include tape frame substrates or carrier substrates. In some embodiments, the second type of substrates 1112b include a plurality of dies disposed on a tape frame or carrier plate. In some embodiments, the second type of substrates 1112b may hold different types and sizes of component dies or dummy dies. As such, the one or more second load ports 1114b may have different sizes or receiving surfaces configured to load the second type of substrates 1112b having different sizes. In some embodiments, the plurality of load ports 1114 are arranged along a common side of the EFEM 1102. Although FIG. 11 depicts a pair of the first load ports 1114a and a pair of the second load ports 1114b, the EFEM 1102 may include other combinations of load ports such as one first load port 1114a and three second load ports 1114b. In addition, the integrated hybrid bonding tool 1100 may also incorporate a buffer 1190 that provides temporary storage or buffering for sources and targets alike. The buffer 1190 aids in allowing different sizes of dummy dies to meet timing and other factors and/or constraints by making the targets and/or sources (component and/or dummy dies) readily available for processing without requiring external retrieval.

In some embodiments, the EFEM 1102 includes a scanning station 1108 having substrate ID readers for scanning the one or more types of substrates 1112 for identifying information. In some embodiments, the substrate ID readers include a bar code reader or an optical character recognition (OCR) reader. The integrated hybrid bonding tool 1100 is configured to use any identifying information from the one or more types of substrates 1112 that are scanned to determine processing based on the identifying information, for example, different processes and/or placements for the first type of substrates 1112a and the second type of substrates 1112b. In some embodiments, the scanning station 1108 may also be configured for rotational movement to align the first type of substrates 1112a or the second type of substrates 1112b. In some embodiments, the one or more of the plurality of automation modules 1110 include a scanning station 1108. An EFEM robot 1104 is disposed in the EFEM 1102 and configured to transport the first type of substrates 1112a and the second type of substrates 1112b between the plurality of load ports 1114 to the scanning station 1108. The EFEM robot 1104 may include substrate end effectors for handling the first type of substrates 1112a and second end effectors for handling the second type of substrates 1112b. The EFEM robot 1104 may rotate or rotate and move linearly.

The transfer chamber 1116 includes a buffer 1120 configured to hold one or more first type of substrates 1112a. In some embodiments, the buffer 1120 is configured to hold one or more of the first type of substrates 1112a and one or more of the second type of substrates 1112b. The transfer chamber 1116 includes a transfer robot 1126 configured to transfer the first type of substrates 1112a and the second type of substrates 1112b between the buffer 1120, the one or more process chambers 1106, and a buffer disposed in an adjacent automation module of the plurality of automation modules 1110. For example, the transfer robot 1126 in the first automation module 1110a is configured to transfer the first type of substrates 1112a and the second type of substrates 1112b between the first automation module 1110a and the buffer 1120 in the second automation module 1110b. In some embodiments, the buffer 1120 is disposed within the interior volume of the transfer chamber 1116, advantageously reducing the footprint of the overall tool. In addition, the buffer 1120 can be open to the interior volume of the transfer chamber 1116 for ease of access by the transfer robot 1126.

The one or more process chambers 1106 may include atmospheric chambers that are configured to operate under atmospheric pressure and vacuum chambers that are configured to operate under vacuum pressure. Examples of the atmospheric chambers may generally include wet clean chambers, radiation chambers, heating chambers, metrology chambers, bonding chambers, or the like. Examples of vacuum chambers may include plasma activation chambers. The types of atmospheric chambers discussed above may also be configured to operate under vacuum, if needed. The one or more process chambers 1106 may be any process chambers or modules needed to perform a bonding process, a cleaning process, a radiation process, or the like. In some embodiments, the one or more process chambers 1106 of each of the plurality of automation modules 1110 include at least one of a wet clean chamber 1122, a plasma activation chamber 1130, a degas chamber 1132, a radiation chamber 1134, or a bonder chamber 1140 such that the integrated hybrid bonding tool 1100 includes at least one wet clean chamber 1122, at least one plasma activation chamber 1130, at least one degas chamber 1132, at least one radiation chamber 1134, and at least one bonder chamber 1140. The one or more process chambers 1106 may be arranged in any suitable location of the integrated hybrid bonding tool 1100.

The wet clean chamber 1122 is configured to perform a wet clean process to clean the one or more types of substrates 1112 via a fluid, such as water. The wet clean chamber 1122 may include a first wet clean chamber 1122a for cleaning the first type of substrates 1112a or a second wet clean chamber 1122b for cleaning the second type of substrates 1112b. The degas chamber 1132 is configured to perform a degas process to remove moisture via, for example, a high temperature baking process. In some embodiments, the degas chamber 1132 includes a first degas chamber 1132a and a second degas chamber 1132b. The plasma activation chamber 1130 may be configured to perform an activation process on a substrate in preparation for hybrid bonding. The activation aids in increasing bonding strength between surfaces. In some embodiments, the plasma activation chamber 1130 includes a first plasma activation chamber 1130a and a second plasma activation chamber 1130b. The radiation chamber 1134 is configured to perform a radiation process to reduce adhesion between dies on a source such as, for example, a tape frame substrate or a carrier substrate with reconstituted dies. For example, the radiation chamber 1134 may be an ultraviolet radiation chamber configured to direct ultraviolet radiation at the source or a heating chamber configured to heat the source. The reduced adhesion between the dies and the source facilitates easier removal of the dies from the source. The bonder chamber 1140 is configured to transfer and bond at least a portion of the dies from a source to the target. The bonder chamber 1140 generally includes a first support 1142 to support one of the first type of substrates 1112a and a second support 1144 to support one of the second type of substrates 1112b.

In some embodiments, a last automation module of the plurality of automation module 1110, for example the third automation module 1110c of FIG. 11, includes one or more bonder chambers 1140 (two shown in FIG. 11). In some embodiments, a first of the two bonder chambers is configured to remove and bond component dies and a second of the two bonder chambers is configured to remove and bond dummy dies. In some embodiments, any of the plurality of automation modules 1110 include a metrology chamber 1118 configured to take measurements of the one or more types of substrates. In FIG. 11, the metrology chamber 1118 is shown as a part of the second automation module 1110b coupled to the transfer chamber 1116 of the second automation module 1110b. However, the metrology chamber 1118 may be coupled to any transfer chamber 1116 or within the transfer chamber 1116.

A controller 1180 controls the operation of any of the integrated hybrid bonding tools described herein, including the integrated hybrid bonding tool 1100. The controller 1180 may use a direct control of the integrated hybrid bonding tool 1100, or alternatively, by controlling the computers (or controllers) associated with the integrated hybrid bonding tool 1100. In operation, the controller 1180 enables data collection and feedback from the integrated hybrid bonding tool 1100 to optimize performance of the integrated hybrid bonding tool 1100 and to control the processing flow according to methods described herein such as selecting and bonding dummy dies to a bonding wafer with component dies bonded to the bonding wafer. The controller 1180 generally includes a central processing unit (CPU) 1182, a memory 1184, and a support circuit 1186. The CPU 1182 may be any form of a general-purpose computer processor that can be used in an industrial setting. The support circuit 1186 is conventionally coupled to the CPU 1182 and may comprise a cache, clock circuits, input/output subsystems, power supplies, and the like. Software routines, such as methods as described herein may be stored in the memory 1184 and, when executed by the CPU 1182, transform the CPU 1182 into a specific purpose computer (controller 1180). The software routines may also be stored and/or executed by a second controller (not shown) that is located remotely from the integrated hybrid bonding tool 1100.

The memory 1184 is in the form of computer-readable storage media that contains instructions, when executed by the CPU 1182, to facilitate the operation of the semiconductor processes and equipment. The instructions in the memory 1184 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for dummy die placement on a bonding wafer, comprising:
receiving bonding wafer parameters for the bonding wafer;
receiving component die size parameters for at least one component die and component die positioning parameters of the at least one component die for the bonding wafer;
receiving bonding wafer processing information for at least one subsequent post-bonding process for the bonding wafer;
determining dummy die size parameters, dummy die material composition, or dummy die positioning parameters on the bonding wafer based on the at least one subsequent post-bonding process or thermal behavior of a dummy die material or a wafer material of the bonding wafer;
selecting at least one dummy die according to the dummy die size parameters, dummy die material composition, or dummy die positioning parameters; and
bonding the at least one dummy die on the bonding wafer according to the dummy die positioning parameters.

2. The method of claim 1, wherein the bonding wafer parameters include a size of the bonding wafer or a material composition of the bonding wafer.

3. The method of claim 1, wherein the component die size parameters include a width, a length, and a height of a component die.

4. The method of claim 1, wherein the dummy die size parameters include a width, a length, and a height for a dummy die.

5. The method of claim 1, wherein the dummy die material composition includes dielectric material and metallic material.

6. The method of claim 1, further comprising:
using a machine learning model that receives the bonding wafer parameters, the component die size parameters, the component die positioning parameters, and the bonding wafer processing information and infers the dummy die size parameters, the dummy die material composition, or the dummy die positioning parameters for the bonding wafer.

7. The method of claim 6, further comprising:
using the machine learning model to infer dummy die size parameters and dummy die positioning parameters that maintain edge uniformity of the bonding wafer during the at least one subsequent post-bonding process.

8. The method of claim 6, further comprising:
using the machine learning model to infer dummy die size parameters and dummy die positioning parameters that reduce step height differences between the at least one component die bonded on the bonding wafer and a surrounding area of the at least one component die bonded on the bonding wafer.

9. The method of claim 1, further comprising:
determining the dummy die material composition based on thermal expansion or conduction properties of the at least one component die.

10. The method of claim 1, wherein the at least one subsequent post-bonding process includes an annealing process, a chemical mechanical planarization (CMP) process, a chemical vapor deposition (CVD) gapfill process, or a plating gapfill process.

11. The method of claim 1, further comprising:
performing the method of claim 1 integrated into an integrated hybrid bonding tool; or
performing the method of claim 1 external to the integrated hybrid bonding tool.

12. A method for dummy die placement on a bonding wafer, comprising:
receiving bonding wafer parameters for the bonding wafer, wherein the bonding wafer parameters include a size of the bonding wafer or a material composition of the bonding wafer;
receiving component die size parameters for at least one component die and component die positioning parameters of the at least one component die for the bonding wafer, wherein the component die size parameters include a width, a length, and a height of the component die;
receiving bonding wafer processing information for at least one subsequent post-bonding process for the bonding wafer;
inferring dummy die size parameters, dummy die material composition, or dummy die positioning parameters on the bonding wafer using a machine learning model that incorporates the bonding wafer parameters, the component die size parameters, the component die positioning parameters, and the bonding wafer processing information to select at least one dummy die; and
bonding the at least one dummy die on the bonding wafer according to the dummy die positioning parameters.

13. The method of claim 12, wherein the dummy die size parameters include a width, a length, and a height for a dummy die.

14. The method of claim 12, wherein the dummy die material composition includes dielectric material and metallic material.

15. The method of claim 12, further comprising:
using the machine learning model to infer dummy die size parameters and dummy die positioning parameters that maintain edge uniformity of the bonding wafer during the at least one subsequent post-bonding process.

16. The method of claim 12, further comprising:
using the machine learning model to infer dummy die size parameters and dummy die positioning parameters that reduce step height differences between the at least one component die bonded on the bonding wafer and a surrounding area of the at least one component die bonded on the bonding wafer.

17. The method of claim 12, further comprising:
determining the dummy die material composition based on thermal expansion or conduction properties of the at least one component die.

18. A non-transitory, computer readable medium having instructions stored thereon that, when executed, cause a method for dummy die placement on a bonding wafer to be performed, the method comprising:
receiving bonding wafer parameters for the bonding wafer;
receiving component die size parameters for at least one component die and component die positioning parameters of the at least one component die for the bonding wafer;
receiving bonding wafer processing information for at least one subsequent post-bonding process for the bonding wafer;
determining dummy die size parameters, dummy die material composition, or dummy die positioning parameters on the bonding wafer based on the at least one subsequent post-bonding process or thermal behavior of a dummy die material or a wafer material of the bonding wafer;
selecting at least one dummy die according to the dummy die size parameters, dummy die material composition, or dummy die positioning parameters; and
bonding the at least one dummy die on the bonding wafer according to the dummy die positioning parameters.

19. The non-transitory, computer readable medium of claim 18, the method further comprising:
using a machine learning model that receives the bonding wafer parameters, the component die size parameters, the component die positioning parameters, and the bonding wafer processing information and infers the dummy die size parameters, the dummy die material composition, or the dummy die positioning parameters for the bonding wafer.

20. The non-transitory, computer readable medium of claim 18, the method further comprising:
determining dummy die size parameters, dummy die material composition, or dummy die positioning parameters on the bonding wafer based on metrology information of the bonding wafer.
